(19) United States
(12) Patent Application Publication
(10) Pub. No.: US 2017/0358508 A1
(43) Pub. Date: Dec. 14, 2017

(54) MOTHERBOARD OF ARRAY SUBSTRATE AND MANUFACTURING METHOD THEREOF

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jing XUE, Beijing (CN); Yanyan YIN, Beijing (CN); Long ZHAO, Beijing (CN); Haijin WANG, Beijing (CN)

(21) Appl. No.: 15/544,473

(22) PCT Filed: Apr. 7, 2016
(86) PCT No.: PCT/CN2016/078663

§ 371 Date: Jul. 18, 2017

(30) Foreign Application Priority Data
Jun. 16, 2015 (CN) 201510335191.1

(51) Int. Cl. H01L 21/66; H01L 27/12; G02F 1/1343; G02F 1/1368; G02F 1/1333; G02F 1/1362

(52) U.S. Cl. CPC H01L 22/34; G02F 1/1368; G02F 1/133345; H01L 27/1259; G02F 1/13439; H01L 27/124; G02F 2001/136254; G02F 2201/121; G02F 2201/123; G02F 2201/124; G02F 2201/50

(57) ABSTRACT

Embodiments of the present disclosure provide a motherboard of an array substrate and a manufacturing method thereof. The motherboard of an array substrate includes a plurality of display areas and a plurality of non-display areas. The non-display area is located between adjacent display areas. The display area includes a first pixel unit configured for display. The non-display area includes a second pixel unit configured to test a characteristic of a thin film transistor on the motherboard of an array substrate. Through the second pixel unit, a characteristic of a thin film transistor on the non-display area may be tested, thereby being able to reflect a characteristic of a thin film transistor on the display area.

### CROSS REFERENCE TO RELATED APPLICATIONS

This patent application is a National Stage Entry of PCT/CN2016/078663 filed on Apr. 7, 2016, which claims the benefit and priority of Chinese Patent Application No. 201510335191.1 filed on Jun. 16, 2015, the disclosures of which are incorporated herein in their entirety as part of the present application.

### BACKGROUND

The present disclosure relates to the technical field of display, and more particularly, to a motherboard of an array substrate and a manufacturing method thereof.

Thin film transistor-liquid crystal display panel (TFT-LCD) is a flat panel display device. Because of its advantages of small size, low power consumption, no radiation, and relatively low production cost, it is applied in the field of high-performance display more and more.

A conventional liquid crystal display panel mainly includes an array substrate, a color film substrate, and a liquid crystal layer, wherein a plurality of thin film transistors (TFT) are formed on the array substrate. After the manufacturing process for the array substrate is completed, it is usually required to test characteristics of the thin film transistors on the array substrate. However, since thin film transistors on an array substrate are usually covered by a protective layer, the test of the characteristic of the thin film transistor is very inconveniently. Especially for a liquid crystal display panel in an advanced super-dimensional switching (ADS) mode, there is no effective way currently to confirm the characteristic of TFT in a display area, after the manufacturing process of the array substrate is completed. Thus, it cannot be determined accurately whether a characteristic of thin film transistor in a display area is abnormal, thereby resulting in great inconvenience to subsequent development work. The development efficiency is affected, and moreover, an occurred problem cannot be resolved in the first time. The production cost increases potentially.

### BRIEF DESCRIPTION

Embodiments of the present disclosure provide a motherboard of an array substrate and a manufacturing method thereof, which may facilitate the test of a characteristic of a thin film transistor on the motherboard of an array substrate.

A first aspect of the present disclosure provides a motherboard of an array substrate including a plurality of display areas and a plurality of non-display areas. The non-display area is located between adjacent display areas. The display area includes a first pixel unit configured for display. The non-display area includes a second pixel unit configured to test a characteristic of a thin film transistor on the motherboard of an array substrate.

In embodiments of the present disclosure, the first pixel unit includes a first thin film transistor and a first pixel electrode connected to the first thin film transistor. The first pixel electrode is covered with an insulating protective layer. The second pixel unit includes a second thin film transistor and a second pixel electrode connected to the second thin film transistor. The second pixel electrode is exposed to input and/or output a test signal.

In embodiments of the present disclosure, the first thin film transistor and the second thin film transistor are formed simultaneously, and the first pixel electrode and the second pixel electrode are formed simultaneously.

In embodiments of the present disclosure, the second pixel electrode is located below or above a drain electrode of the second thin film transistor.

In embodiments of the present disclosure, a common electrode is provided on the insulating protective layer. Both the first pixel electrode and the second pixel electrode are planar electrodes, and the common electrode is a comb-shaped electrode.

A second aspect of the present disclosure provides a manufacturing method for a motherboard of an array substrate. The motherboard of an array substrate includes a plurality of display areas and a plurality of non-display areas. The non-display areas are located between adjacent display areas. The manufacturing method includes manufacturing a first pixel unit in the display area. The first pixel unit is configured for display. The manufacturing method further includes manufacturing a second pixel unit in the non-display area. The second pixel unit is configured to test a characteristic of a thin film transistor on the motherboard of an array substrate.

In embodiments of the present disclosure, the first pixel unit includes a first thin film transistor and a first pixel electrode connected to the first thin film transistor. The first pixel electrode is covered with an insulating protective layer. The second pixel unit includes a second thin film transistor and a second pixel electrode connected to the second thin film transistor. The second pixel electrode is exposed to input and/or output a test signal.

In embodiments of the present disclosure, the first thin film transistor and the second thin film transistor are formed simultaneously, and the first pixel electrode and the second pixel electrode are formed simultaneously.

In embodiments of the present disclosure, the second pixel electrode is located below or above a drain electrode of the second thin film transistor.

In embodiments of the present disclosure, a common electrode is provided on the insulating protective layer. Both the first pixel electrode and the second pixel electrode are planar electrodes, and the common electrode is a comb-shaped electrode.

Embodiments of the present disclosure provide a motherboard of an array substrate. A first pixel unit is provided in a display area, and a second pixel unit is provided in a non-display area between two adjacent display areas. In adjacent display area and non-display area, thin film transistors in the first pixel unit and in the second pixel unit have the same or similar characteristics. By testing the second pixel unit to understand a characteristic of a thin film transistor in the non-display area, it is possible to reflect a characteristic of a thin film transistor in the adjacent display area well. It is advantageous in finding a defect of the thin film transistors on the motherboard of an array substrate. The corresponding countermeasures may be taken to avoid a subsequence of a large number of bad products. Material may be saved, and product development may be improved.

### BRIEF DESCRIPTION OF THE DRAWINGS

In order to more clearly illustrate the technical solutions of the embodiments of the present disclosure, the drawings of the embodiments will be briefly described below. It should be understood that the drawings described below merely relate to some embodiments of the present disclosure, rather than limit the present disclosure, in which:

FIG. 1 is a schematic diagram of a motherboard of an array substrate provided in embodiments of the present disclosure;

FIG. 2 is a schematic diagram of pixel units on a display area and a non-display area on a motherboard of an array substrate provided in embodiments of the present disclosure; and

FIG. 3 is a schematic diagram of pixel units on a display area and a non-display area on another motherboard of an array substrate provided in embodiments of the present disclosure.

### DETAILED DESCRIPTION

Hereinafter, the embodying manner of the present disclosure will be further described in detail, in combination with the accompanying drawings and embodiments. The following embodiments are intended to illustrate the disclosure, rather than limit the scope of the disclosure.

Embodiments of the present disclosure provide a motherboard of an array substrate, including a plurality of display areas and a plurality of non-display areas. The non-display area is located between adjacent display areas. The display area includes a first pixel unit configured for display. The non-display area includes a second pixel unit configured to test a characteristic of a thin film transistor on the motherboard of an array substrate.

In the motherboard of an array substrate provided in embodiments of the present disclosure, a second pixel unit is provided in a non-display area between two adjacent display areas. With the second pixel unit, it is possible to test a characteristic of a thin film transistor on the non-display area, which is able to reflect a characteristic of a thin film transistor on the display area. It is advantageous in finding defects of the thin film transistors on the motherboard of an array substrate. A subsequence of a large number of bad products may be avoided. Material may be saved, and product development may be improved.

The motherboard of an array substrate in the present disclosure may be cut to form a plurality of independent array substrates for display devices, each of which includes a display area and a peripheral non-display area on the motherboard of an array substrate. The display area of the array substrate corresponds to a display area of the display device, and the non-display area may correspond to a bezel position of the display device.

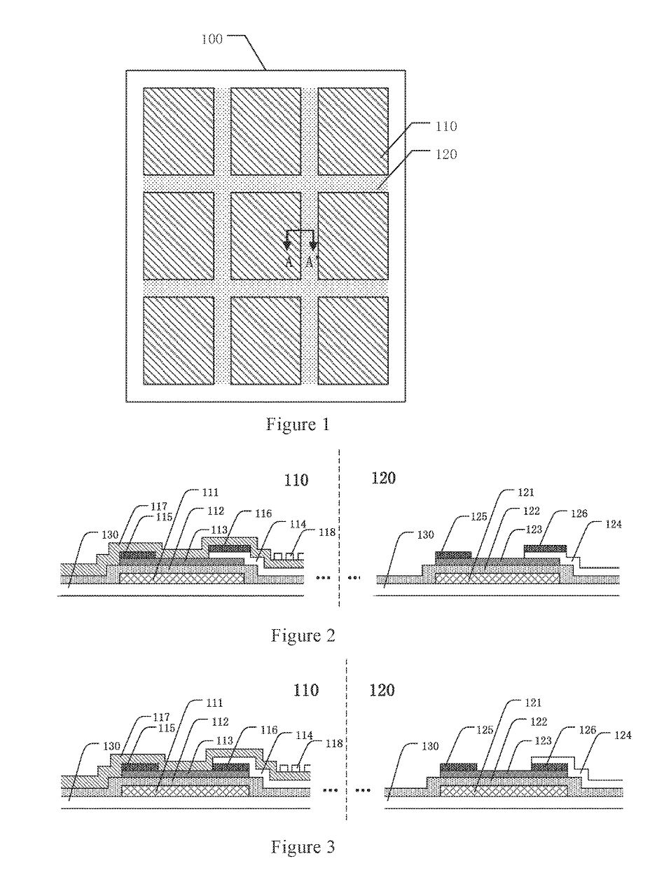

FIG. 1 is a schematic diagram of a motherboard of an array substrate provided in embodiments of the present disclosure. In FIG. 1, the motherboard of an array substrate 100 includes a plurality of display areas 110 and non-display areas 120 between any two adjacent display areas.

The display area 110 is provided with a plurality of crossed gate lines and data lines. A plurality of first pixel units are divided and arranged in a matrix by the plurality of crossed gate lines and data lines. Each of the plurality of first pixel units is used for controlling the twist of liquid crystal molecules in a corresponding area in the liquid crystal layer, so as to enable the display device to display the corresponding picture.

The non-display area 120 may likewise be provided with a plurality of crossed gate lines and data lines, so as to obtain a plurality of second pixel units arranged in a matrix, for testing a characteristic of a thin film transistor (also referred as TFT Character) on the motherboard of an array substrate.

FIG. 2 is a schematic diagram of pixel units on a display area and a non-display area on a motherboard of an array substrate provided in embodiments of the present disclosure, and a cross section in the direction of AN as shown in FIG. 1. Specifically, in FIG. 2, in the display area 110, each of the first pixel units includes a first thin film transistor and a first pixel electrode 114 connected to the first thin film transistor. The first thin film transistor includes a gate electrode 111, a gate insulating layer 112, an active layer 113, a source electrode 115, and a drain electrode 116 provided on a base substrate 130. The gate electrode 111 is connected to a gate line in the display area, the source electrode 115 is connected to a data line in the display area, and the drain electrode 116 is connected to the first pixel electrode 114. An insulating protective layer (PVX layer) 117 is further formed on the source electrode 115, the drain electrode 116, and the first pixel electrode 114. The first pixel electrode 114 is isolated from the common electrode 118 by the insulating protective layer 117.

In the non-display area 120, the second pixel unit includes a second thin film transistor and a second pixel electrode 124 connected to the second thin film transistor. The second thin film transistor includes a gate electrode 121, a gate insulating layer 122, an active layer 123, a source electrode 125, and a drain electrode 126 provided on the base substrate 130. The gate electrode 121 is connected to a gate line in this area, the source electrode 125 is connected to a data line in this area, and the drain electrode 126 is connected to the second pixel electrode 124. Unlike the first pixel unit in the display area, the second pixel electrode in the non-display area is exposed to input and/or output a test signal.

When testing a characteristic of a thin film transistor on the above-mentioned motherboard of an array substrate, the characteristic of the thin film transistor in the non-display area can be determined, only by applying a test signal to the second pixel electrode, a data driven chip (IC), a gate driven circuit (e.g. a GOA unit) in the non-display area, and detecting the corresponding feedback signal. Since the non-display area is located between two display areas, the characteristic of the thin film transistor in the display area can be also reflected well. Thus, more accurate test value of the characteristic of the thin film transistor in the display area may be obtained, and further, TFT-related defects may be found at the first time.

In embodiments of the present disclosure, to make the test value of the characteristic of the thin film transistor in the non-display area closer to the characteristic of the thin film transistor in the display area, the first thin film transistor is formed simultaneously with the second thin film transistor, and the first pixel electrode is formed simultaneously with the second pixel electrode.

In the motherboard of an array substrate provided by the present disclosure, the first thin film transistor has the same structure as the second thin film transistor, and the first pixel electrode has the same structure as the second pixel electrode. The test can be done well only by exposing the second pixel electrode in the non-display area. Therefore, in the manufacturing process for the insulating protective layer (PVX layer), the PVX material may not be deposited over the whole non-display area, or the PVX material may not be deposited only on the area of the second pixel electrode. For example, the manufacturing processes for the gate line, the data line, the thin film transistor, and the pixel electrode of the non-display area can be completed in synchronization with the display area in a conventional manufacturing process for array substrates. The subsequent manufacturing process of the insulating protective layer and the common electrode is performed only for the display area. Thus, the display area is formed with a capacitor composed of the common electrode and the first pixel electrode, and only the thin film transistor and the pixel electrode are manufactured in the non-display area. As a result, the second pixel electrode is exposed.

In addition, it is possible to make the non-display area and the display area identical in the existing manufacturing process. After all the existing processes are completed, the insulating protective layer and the common electrode layer on the entire non-display area are removed, or only the insulating protective layer and the common electrode layer on the second pixel electrode are removed. As a result, the above-mentioned motherboard of an array substrate is also obtained.

In addition, in the present disclosure, as shown in FIG. 2, the first pixel electrode may be located below the drain electrode of the first thin film transistor, and the second pixel electrode may be located below the drain electrode of the second thin film transistor, but this is not to limit the disclosure.

FIG. 3 is a schematic diagram of pixel units on a display area and a non-display area on another motherboard of an array substrate provided in embodiments of the present disclosure. As shown in FIG. 3, the first pixel electrode is located above the drain electrode of the first thin film transistor, and the second pixel electrode is located above the drain electrode of the second thin film transistor. As shown in FIG. 3, when manufacturing a pixel electrode, it is possible to use an etching solution that does not corrode the source and drain electrode layers, so as to prevent damage to the source and drain electrodes.

The motherboard of an array substrate in embodiments of the present disclosure may be in an ADS mode. In the motherboard of an array substrate in this mode, both the first pixel electrode and the second pixel electrode are planar electrodes and the common electrode is a comb-shaped electrode.

Embodiments of the present disclosure provide the motherboard of an array substrate. A second pixel unit is provided in a non-display area between two adjacent display areas. A pixel electrode of the second pixel unit is exposed. Through the pixel electrode of the second pixel unit, a test signal may be inputted or outputted, to obtain a characteristic of the thin film transistor on the non-display area. Since the non-display area is located between two display areas, the characteristic of the thin film transistor in the display area are also well reflected. A test value closer to the characteristic of the thin film transistor on the display area may be obtained. It is advantageous in finding the TFT switch defects on the motherboard of an array substrate in time. The subsequence of a large number of bad products may be avoided. Material may be saved, and product development may be improved. In addition, since the second pixel unit is provided in the non-display area, the height difference between the non-display area and the display area can be reduced. Further, the rubbing Mura can be prevented in the subsequent rubbing orientation process.

Embodiments of the present disclosure further provide a manufacturing method for a motherboard of an array substrate. The motherboard of an array substrate includes a plurality of display areas and a plurality of non-display areas. The non-display area is located between adjacent display areas. The manufacturing method includes manufacturing a first pixel unit in a display area. The first pixel unit is configured for display. The manufacturing method further includes manufacturing a second pixel unit. The second pixel unit is configured to test the characteristic of the thin film transistor on the motherboard of an array substrate.

The first pixel unit includes a first thin film transistor and a first pixel electrode connected to the first thin film transistor. The first pixel electrode is covered with an insulating protective layer. The second pixel unit includes a second thin film transistor and a second pixel electrode connected to the second thin film transistor. The second pixel electrode is exposed to input and/or output a test signal.

In embodiments of the present disclosure, to make the test value of the thin film transistor obtained as described above closer to the characteristic of the thin film transistor in the display area, the first thin film transistor is formed simultaneously with the second thin film transistor, and the first pixel electrode is formed simultaneously with the second pixel electrode.

In embodiments of the present disclosure, the second pixel electrode may be located below or above the drain electrode of the second thin film transistor.

In embodiments of the present disclosure, the above method can be used for manufacturing an ADS mode product. In the motherboard of an array substrate in this mode, both the first pixel electrode and the second pixel electrode are planar electrodes, and the common electrode is a comb-shaped electrode.

The above embodiments are merely illustrative of the present disclosure and are not intended to limit the present disclosure, and various changes and modifications may be made by those of ordinary skill in the art without departing from the spirit and scope of the disclosure. Therefore, all the equivalent technical solutions are also within the scope of the present disclosure, and the scope of patent protection of the present disclosure is defined by the claims.

1. A motherboard of an array substrate comprising:
a plurality of display areas; and
a plurality of non-display areas;
wherein at least one non-display area is located between adjacent display areas;
wherein at least one display area comprises a first pixel unit configured for display; and
wherein the at least one non-display area comprises a second pixel unit configured to test a characteristic of a thin film transistor on the motherboard of the array substrate.

2. The motherboard of an array substrate according to claim 1,
wherein the first pixel unit comprises a first thin film transistor and a first pixel electrode connected to the first thin film transistor;
wherein the first pixel electrode is covered with an insulating protective layer;
wherein the second pixel unit comprises a second thin film transistor and a second pixel electrode connected to the second thin film transistor; and
wherein the second pixel electrode is exposed to at least one of input and output a test signal.

3. The motherboard of an array substrate according to claim 2,
wherein the first thin film transistor and the second thin film transistor are formed simultaneously; and
wherein the first pixel electrode and the second pixel electrode are formed simultaneously.

4. The motherboard of an array substrate according to claim 3, wherein the second pixel electrode is located one of below and above a drain electrode of the second thin film transistor.

5. The motherboard of an array substrate according to claim 2,
wherein a common electrode is provided on the insulating protective layer;
wherein both the first pixel electrode and the second pixel electrode are planar electrodes; and
wherein the common electrode is a comb-shaped electrode.

6. A manufacturing method for a motherboard of an array substrate, wherein the motherboard of the array substrate comprises a plurality of display areas and a plurality of non-display areas, and wherein at least one non-display area is located between adjacent display areas, the method, comprising:
manufacturing a first pixel unit in at least one display area, wherein the first pixel unit is configured for display; and
manufacturing a second pixel unit in the at least one non-display area, wherein the second pixel unit is configured to test a characteristic of a thin film transistor on the motherboard of the array substrate.

7. The manufacturing method for a motherboard of an array substrate according to claim 6,
wherein the first pixel unit comprises a first thin film transistor and a first pixel electrode connected to the first thin film transistor;
wherein the first pixel electrode is covered with an insulating protective layer;
wherein the second pixel unit comprises a second thin film transistor and a second pixel electrode connected to the second thin film transistor; and
wherein the second pixel electrode is exposed to at least one of input and output a test signal.

8. The manufacturing method for a motherboard of an array substrate according to claim 7,
wherein the first thin film transistor and the second thin film transistor are formed simultaneously; and
wherein the first pixel electrode and the second pixel electrode are formed simultaneously.

9. The manufacturing method for a motherboard of an array substrate according to claim 8, wherein the second pixel electrode is located one of below and above the drain electrode of the second thin film transistor.

10. The manufacturing method for a motherboard of an array substrate according to claim 7,
wherein a common electrode is provided on the insulating protective layer;
wherein both the first pixel electrode and the second pixel electrode are planar electrodes; and
wherein the common electrode is a comb-shaped electrode.
